(19) United States
(12) Patent Application Publication
(10) Pub. No.: US 2018/0233451 A1
(43) Pub. Date: Aug. 16, 2018

(54) PAD STRUCTURE AND METHOD FOR FABRICATING THE SAME

(71) Applicants: UNITED MICROELECTRONICS CORP., Hsin-Chu City (TW); Fujian Jinhua Integrated Circuit Co., Ltd., Quanzhou City (CN)

(72) Inventors: Feng-Yi Chang, Tainan City (TW); Fu-Che Lee, Taichung City (TW); Chieh-Te Chen, Kaohsiung City (TW)

(21) Appl. No.: 15/466,881

(22) Filed: Mar. 23, 2017

(30) Foreign Application Priority Data
Feb. 15, 2017 (CN) 201710081029.0

(51) Int. Cl. H01L 23/535; H01L 21/768; H01L 21/3213

(52) U.S. Cl. CPC H01L 23/535; H01L 21/76895; H01L 21/32139; H01L 21/76883; H01L 21/76802

(57) ABSTRACT

A method for fabricating a pad structure includes the steps of: providing a material layer; forming an opening in the material layer; forming a conductive layer on the material layer and into the opening; forming a patterned mask on the conductive layer; performing a first etching process to remove part of the conductive layer for forming a conductive plug; and performing a shaping process to alter the shape of a top surface of the conductive plug.

### BACKGROUND OF THE INVENTION

### 1. Field of the Invention

The invention relates to a method for fabricating pad structures, and more particularly to a method for fabricating storage node pads for dynamic random access memory (DRAM) device.

### 2. Description of the Prior Art

As electronic products develop toward the direction of miniaturization, the design of dynamic random access memory (DRAM) units also moves toward the direction of higher integration and higher density. Since the nature of a DRAM unit with buried gate structures has the advantage of possessing longer carrier channel length within a semiconductor substrate thereby reducing capacitor leakage, it has been gradually used to replace conventional DRAM unit with planar gate structures.

Typically, a DRAM unit with buried gate structure includes a transistor device and a charge storage element to receive electrical signals from bit lines and word lines. Nevertheless, current DRAM units with buried gate structures still pose numerous problems due to limited fabrication capability. Hence, how to effectively improve the performance and reliability of current DRAM device has become an important task in this field.

### SUMMARY OF THE INVENTION

According to an embodiment of the present invention, a method for fabricating a pad structure includes the steps of: providing a material layer; forming an opening in the material layer; forming a conductive layer on the material layer and into the opening; forming a patterned mask on the conductive layer; performing a first etching process to remove part of the conductive layer for forming a conductive plug; and performing a shaping process to alter the shape of a top surface of the conductive plug.

According to another aspect of the present invention, a pad structure includes: a material layer; and a conductive plug in the material layer and protruding from a top surface of the material layer. Preferably, a top surface of the conductive plug includes a curved surface.

According to another aspect of the present invention, a pad structure includes: a material layer; and a conductive plug in the material layer and protruding from a top surface of the material layer. Preferably, a top portion of conductive plug includes a slanted sidewall.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-2 illustrate a method for fabricating a semiconductor device according to an embodiment of the present invention.

FIGS. 3-5 illustrate a method for fabricating storage node pads of DRAM device following FIG. 2 according to a first embodiment of the present invention.

FIGS. 6-8 illustrate a method for fabricating storage node pads of DRAM device following FIG. 3 according to a second embodiment of the present invention.

FIGS. 9-10 illustrate a method for fabricating storage node pads of DRAM device following FIG. 3 according to a third embodiment of the present invention.

FIG. 11 illustrates a structural view of a semiconductor device according to an embodiment of the present invention.

### DETAILED DESCRIPTION

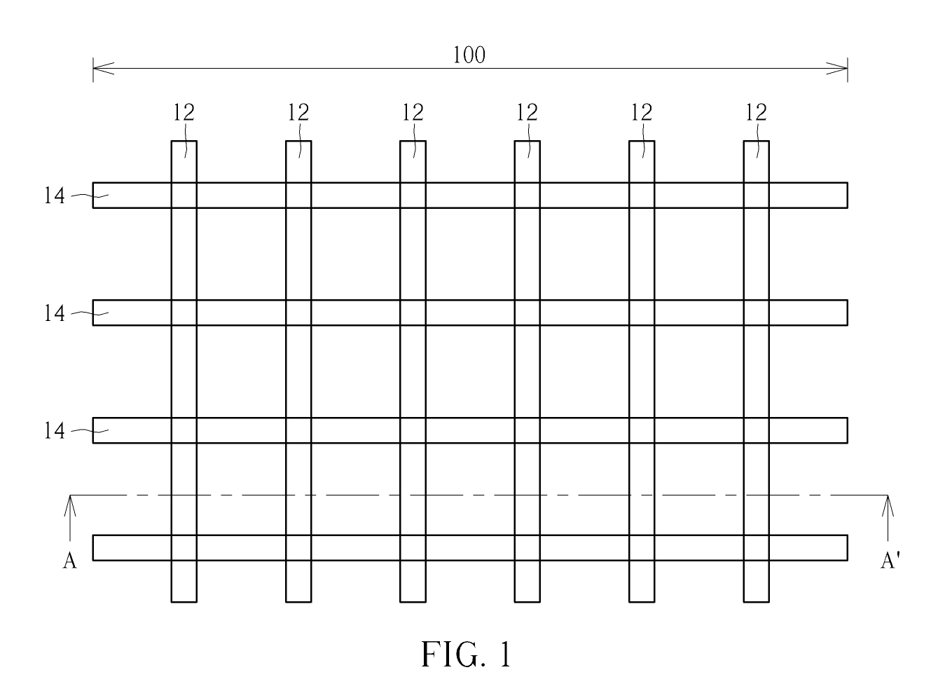

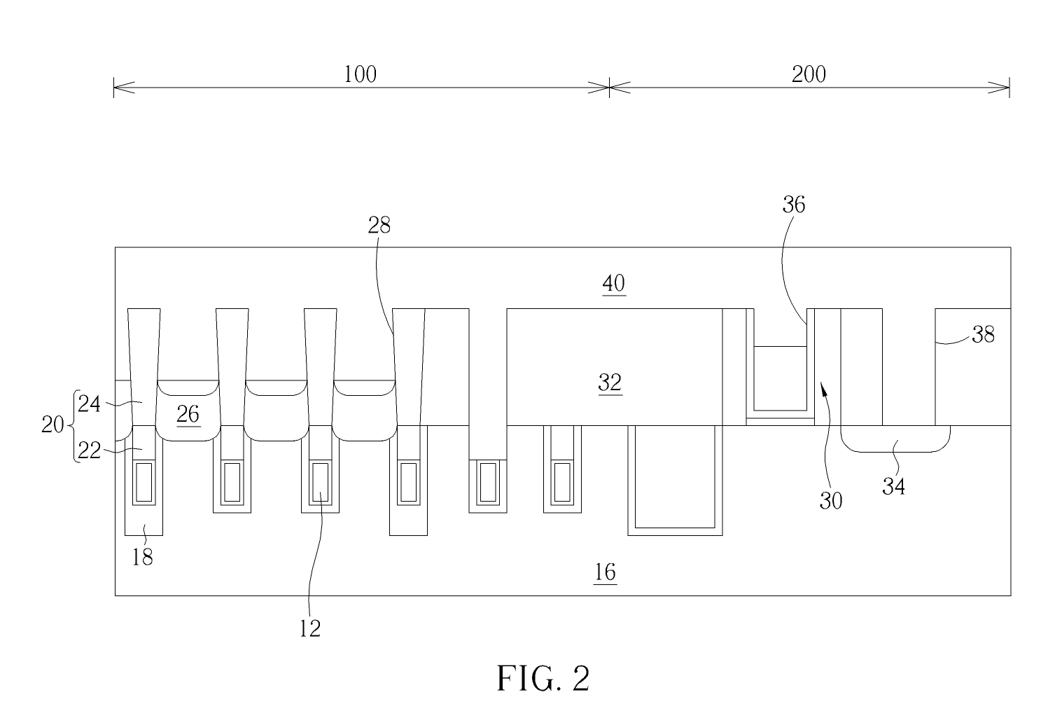

Referring to FIGS. 1-2, FIGS. 1-2 illustrate a method for fabricating a semiconductor device according to an embodiment of the present invention, in which FIG. 1 illustrates a top view perspective while FIG. 2 illustrates a cross-sectional view of FIG. 1 along the sectional line AA′. Preferably, the present invention pertains to a memory device, such as a DRAM device having buried gate structures, which preferably includes at least a transistor element (not shown) and at least a capacitor structure (not shown) for receiving signals from word lines 12 and bit lines 14.

As shown in FIGS. 1-2, a substrate 16 made of silicon is first provided, a memory region 100 is defined on the substrate 16, a plurality of active regions (not shown) and shallow trench isolations (STIs) 18 are formed in the substrate 16 on the memory region, a plurality of word lines 12 are buried in the substrate 16 while part of the word lines 12 are passing through the STIs 18, and a plurality of bit lines (not shown) are formed on the substrate 16 to cross with the word lines 12. A material layer 20 or insulating layer is formed on the word lines 12, in which the material layer 20 could include hard masks 22 and an interlayer dielectric (ILD) layer 24, the material layer 20 could include single-layered or multiple-layered insulating material, and the material layer 20 could include silicon oxide, silicon nitride, silicon oxynitride, or combination thereof. An epitaxial layer 26 could be disposed between the word lines 12 on the substrate 16, a doped region (not shown) could be formed under the epitaxial layer 26 in the substrate 16, and an opening 28 is formed on the epitaxial layer 26 or in the material layer 20.

A peripheral circuit region 200 is also defined on the substrate 16, in which a transistor, such as a planar metal-oxide semiconductor (MOS) transistor 30 could be formed on the peripheral circuit region 200. A dielectric layer 32 is formed on the substrate 16 around the transistor 30, a source/drain region 34 is formed in the substrate 16 adjacent to the transistor 30, and openings 36 and 38 are formed in the dielectric layer 32, in which the opening 36 is formed directly on top of the gate structure of the transistor 30 while opening 38 is formed directly on the source/drain region 34.

Next, a selective barrier layer (not shown) and a conductive layer 40 are formed in the opening 28 on memory region 100 and openings 36, 38 on peripheral circuit region 200, in which the barrier layer could include TiN, TaN, or combination thereof and the conductive layer 40 could include material such as but not limited to for example Al, Cr, Cu, Ta, Mo, W, or combination thereof

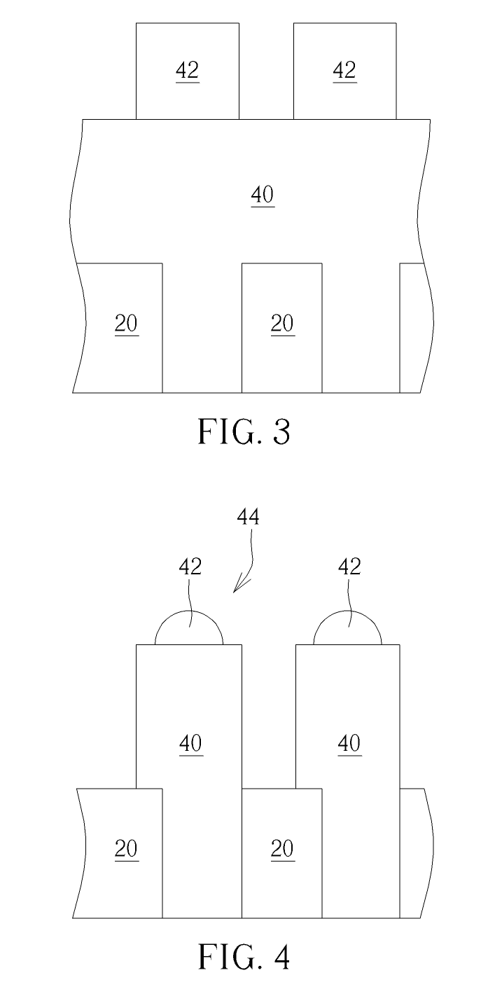

Next, referring to FIGS. 3-5, FIGS. 3-5 illustrate a method for fabricating a storage node pad or capacitor pad after fabricating the DRAM device after FIG. 2 according to a first embodiment of the present invention. It should be noted that to emphasize the structural highlight of the pad itself, only part of the material layer 20 and conductive layer 40 on memory region 100 and/or peripheral circuit region 200 from FIG. 2 are shown in FIGS. 3-5. As shown in FIG. 3, after the conductive layer 40 is deposited into the openings 28, 36, 38, a patterned mask 42 is formed on the conductive layer 40. In this embodiment, the patterned mask 42 preferably includes silicon nitride, but not limited thereto.

Next, as shown in FIG. 4, a first etching process is conducted by using the patterned mask 42 as mask to remove part of the conductive layer 40 for forming a conductive plug 44. Specifically, the first etching process of this embodiment preferably removes part of the patterned mask 42 and part of the conductive layer 40 at the same time while not etching any of the material layer 20, in which the step of removing part of the patterned mask 42 in particular further includes shaping the rectangular patterned mask 42 into a half-moon shape. In this embodiment, an etching gas used in the first etching process could be selected from the group consisting of NF₃, SF₆, CH₂F₂, CH₃F, and CHF₃, in which the etching target of NF₃ and SF₆ is primarily the conductive layer 40 made preferably of tungsten (W) while the etching target of CH₂F₂, CH₃F, and CHF₃ is primarily the patterned mask 42 made of silicon nitride.

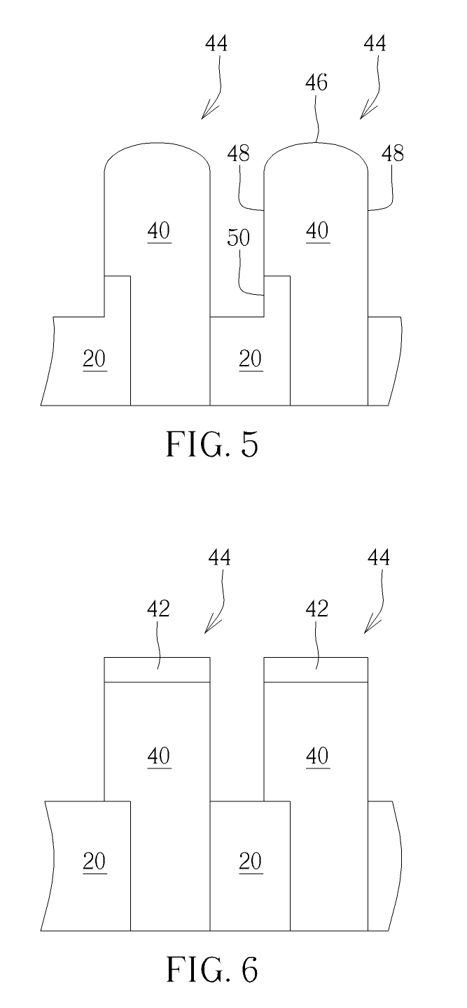

Next, as shown in FIG. 5, a shaping process is conducted to transform the shape of the top portion of conductive plug 44. More specifically, the shaping process at this stage preferably includes conducting a second etching process by using the half-moon shaped patterned mask 42 as mask to remove part of the material layer 20 and part of the conductive plug 44 so that the conductive plug 44 could a curved surface 46.

It should be noted that the step of forming the conductive plug 44 in FIG. 4 to the step of shaping the conductive plug 44 in FIG. 5 are preferably accomplished by adjusting the flow ratio or volume of the etching gas between the conductive layer 40 and material layer 20 so that the top surface of the final conductive plug 44 could reveal a curved surface while part of the material layer 20 is being etched.

For instance, as part of the conductive layer 40 is removed to form the conductive plug 44 in FIGS. 3-4, a higher volume of etching gas targeting the conductive layer 40 is preferably injected while a lower volume of etching gas targeting the patterned hard mask 42 is injected. In other words, the process carried out in FIG. 4 is preferably accomplished by injecting higher volume of etching gas including but not limited to for example NF₃ and SF₆ and lower volume of etching gas including but not limited to for example CH₂F₂, CH₃F, and CHF₃. This patterns the conductive layer 40 into a storage node pad or conductive plug 44 while trimming or shaping the rectangular patterned mask 42 into a substantially half-moon shape.

Next, the shaping process conducted in FIG. 5 is preferably accomplished by injecting a lower volume of etching gas targeting the conductive plug 44 and a higher volume of etching gas targeting the patterned mask 42 and material layer 20. In other words, the process carried out in FIG. 4 is preferably accomplished by injecting a lower volume of etching gas including but not limited to for example NF₃ and SF₆ and a higher volume of etching gas including but not limited to for example CH₂F₂, CH₃F, and CHF₃. This shapes the planar top surface of the conductive plug 44 into a substantially curved surface or profile and at the same time removes the patterned mask 42 completely and part of the material layer 20 not covered by the storage node pad. In this embodiment, an etching selectivity of the etching gas between silicon nitride to tungsten is between 3 to 5 and most preferably at 4, and a thickness of the conductive plug 44 protruding above the top surface of the material layer 20 is between 500 Angstroms to 700 Angstroms and most preferably at 600 Angstroms.

After the second etching process is conducted, as shown in FIG. 5, the top or topmost surface of the conductive plug 44 preferably includes a curved surface 46 and two completely planar and vertical sidewalls 48 are connected to the curved surface 46 directly, in which one of the planar vertical sidewalls 48 is aligned with a vertical edge 50 of the material layer 20.

Referring to FIGS. 3 and 6-8, FIGS. 6-8 illustrate a method for fabricating a storage node pad or capacitor pad after fabricating the DRAM device after FIG. 2 according to a second embodiment of the present invention. As shown in FIG. 3, after the conductive layer 40 is deposited into the openings 28, 36, 38, a patterned mask 42 is formed on the conductive layer 40. In this embodiment, the patterned mask 42 preferably includes silicon nitride, but not limited thereto.

Next, as shown in FIG. 6, a first etching process is conducted by using the patterned mask 42 as mask to remove part of the conductive layer 40 for forming a conductive plug 44 without etching any of the material layer 20. In this embodiment, an etching gas used in the first etching process is preferably selected from the group consisting of NF₃, SF₆, CH₂F₂, CH₃F, and CHF₃, in which the etching target of NF₃ and SF₆ is primarily the conductive layer 40 made preferably of tungsten (W) while the etching target of CH₂F₂, CH₃F, and CHF₃ is the patterned mask 42 made of silicon nitride.

It should be noted that in contrast to the approach of using different volume of etching gas to remove part of the conductive layer 40 and material layer 20 in the first embodiment, the present embodiment preferably controls the etching selectivity ratio of the conductive layer 40 made of tungsten over the material layer 20 made of silicon nitride at 1.5 to 2. By doing so, it would be desirable to maintain the shape of the patterned mask 42 during first etching process as part of the conductive layer 40 is removed to form the conductive plug 44. Specifically, part of the patterned mask 42 is consumed during the etching process while the remaining patterned mask 42 disposed on the conductive plug 44 is still rectangular in shape.

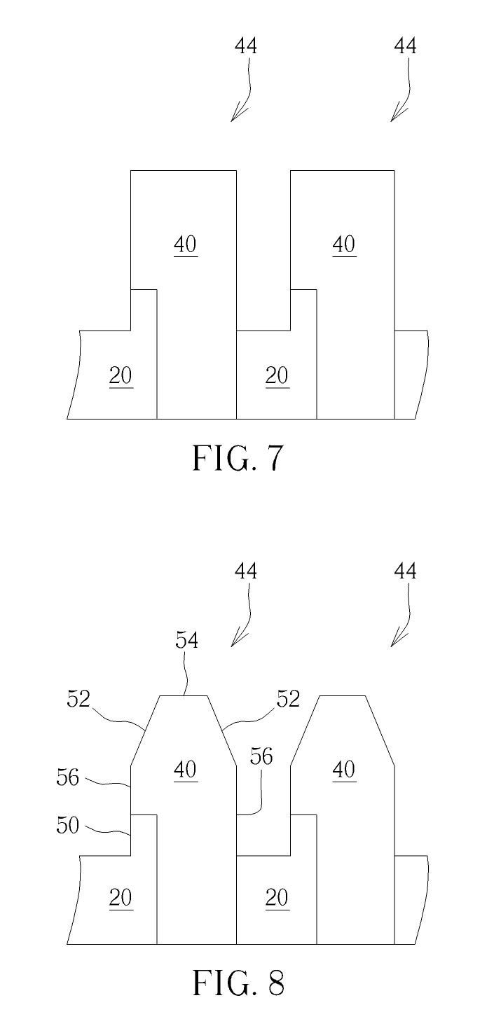

Next, as shown in FIGS. 7-8, a shaping process is conducted to alter the shape of the top portion of the conductive plug 44. Specifically, the shaping process preferably includes two stages of etching process to alter the planar vertical sidewalls of the conductive plug 44 into slanted sidewalls. For instance, as shown in FIG. 7, a second etching process is conducted by using the remaining patterned mask 42 as mask to remove part of the material layer 20, in which all of the remaining patterned mask 42 is consumed during the removal of part of the material layer 20. Next, as shown in FIG. 8, a third etching process is conducted by using no mask at all to remove part of the sidewalls of the conductive plug 44 so that the top portion of the conductive plug 44 reveals at least a slanted sidewall 52 or more preferably symmetrical slanted sidewalls 52 on both left and right sides.

In this embodiment, the content of the etching gas used in the second etching process could be the same as or different from the etching gas used in the first etching process. For instance, an etching gas used in the second etching process could be selected from the group consisting of NF₃, SF₆, CH₂F₂, CH₃F, and CHF₃. An etching gas such as Ar conducted with high power is preferably used as main etchant in the third etching process to remove part of the sidewall of the conductive plug 44 to produce slanted sidewalls 52. Nevertheless, according to an embodiment of the present invention, gases such as NF₃, SF₆, and/or other inert gas could also be added selectively, which is also within the scope of the present invention.

After the third etching process is conducted, as shown in FIG. 8, the storage node pad or conductive plug 44 preferably includes a completely planar top surface 54, two slanted or inclined sidewalls 52 connected to the planar top surface 54, and two planar vertical sidewalls 56 connected to the slanted sidewalls 52, in which a planar vertical sidewall 56 is connected to a sidewalls edge 50 of the material layer 20 directly. It should be noted that even though the top surface of the conductive plug 44 is completely planar in this embodiment, it would also be desirable to incorporate the approach disclosed in the aforementioned embodiment shown in FIG. 5 so that the top or topmost surface 54 of the conductive plug 44 also reveals a curved surface and in this instance, the curved surface would be connected to the two slanted sidewalls 52 directly, which is also within the scope of the present invention.

Referring to FIGS. 3 and 9-10, FIGS. 9-10 illustrate a method for fabricating a storage node pad or capacitor pad after fabricating the DRAM device after FIG. 2 according to a third embodiment of the present invention. As shown in FIG. 3, after the conductive layer 40 is deposited into the openings 28, 36, 38, a patterned mask 42 is formed on the conductive layer 40. In this embodiment, the patterned mask 42 preferably includes silicon nitride, but not limited thereto.

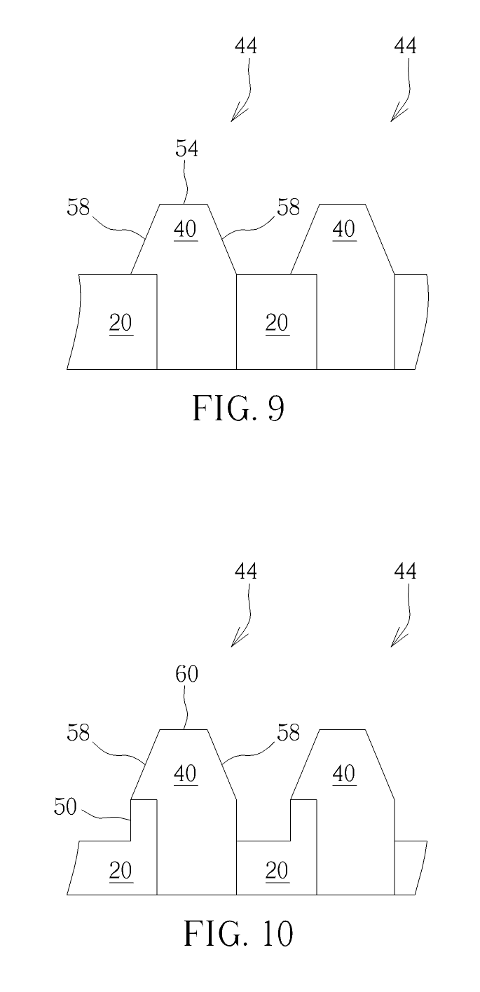

Next, as shown in FIG. 9, a first etching process is conducted by using the patterned mask 42 as mask to remove part of the conductive layer 40 for forming a conductive plug 44 without etching any of the material layer 20. In this embodiment, an etching gas used in the first etching process is preferably selected from the group consisting of NF₃, SF₆, CH₂F₂, CH₃F, and CHF₃, in which the etching target of NF₃ and SF₆ is primarily the conductive layer 40 made preferably of tungsten (W) while the etching target of CH₂F₂, CH₃F, and CHF₃ is the patterned mask 42 made of silicon nitride.

It should be noted that in contrast to the approach of using different volume of etching gas to remove part of the conductive layer 40 and material layer 20 in the first embodiment, the present embodiment preferably controls the etching selectivity ratio of the conductive layer 40 made of tungsten over the material layer 20 made of silicon nitride to be at 0.9 to 1.5 or most preferably 1.0. By doing so, it would be desirable to form slanted sidewalls 58 on the sidewall portion of the conductive plug 44 during the first etching process or more specifically, altering the original vertical sidewalls of the conductive plug 44 into slanted sidewalls 58 so that all the sidewalls of the conductive plug 44 protruding above the material layer 20 are transformed into slanted sidewalls 58. Preferably, the patterned mask 42 is completely removed during the formation of the conductive plug 44.

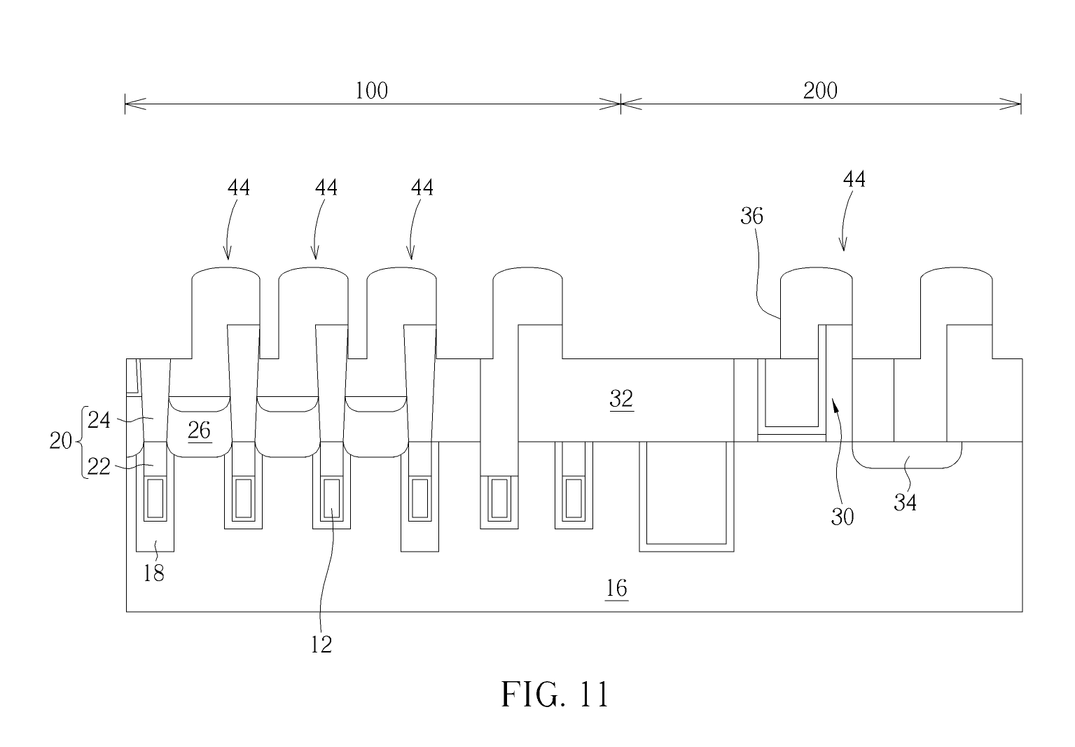

Next, as shown in FIG. 10, a shaping process is conducted to alter the shape of the top portion of the conductive plug 44. Specifically, the shaping process at this stage preferably includes conducting a second etching process by using the slanted sidewalls 58 of the conductive plug 44 as mask to remove part of the material layer 20, in which part of the conductive plug 44 could also be removed during the etching of the material layer 20. In this embodiment, the content of the etching gas used in the second etching process could be the same as or different from the etching gas used in the first etching process. For instance, an etching gas used in the second etching process could be selected from the group consisting of NF₃, SF₆, CH₂F₂, CH₃F, and CHF₃.

After the second etching process is conducted, as shown in FIG. 10, the final conductive plug 44 preferably includes a completely planar top surface 60 and two slanted sidewalls 58 connected to the planar top surface 60 directly, in which the slanted sidewalls 58 also connect to vertical edges or sidewalls 50 of the material layer 20. It should be noted that even though the top surface of the conductive plug 44 is completely planar in this embodiment, it would also be desirable to incorporate the approach disclosed in the aforementioned embodiment shown in FIG. 5 so that the top or topmost surface 60 of the conductive plug 44 in this embodiment also includes a curved surface and in this instance, the curved surface would be connected to the two slanted sidewalls 58 directly, which is also within the scope of the present invention.

Referring to FIG. 11, FIG. 11 is an overall structural view of disposing the storage node pad (or conductive plug 44) or capacitor pad fabricated in FIG. 5 onto the memory region 100 and peripheral circuit region 200 of the DRAM device 10. As shown in FIG. 11, the pads disposed on the memory region 100 could be connected to the epitaxial layers 26 directly while the pads on the peripheral circuit region 200 could be connected to the gate structure and source/drain region 34 of the transistor 30. Next, elements such as storage capacitors could be fabricated on the pads and electrically connected to the word lines through the storage node pads. This completes the fabrication of a DRAM device according to an embodiment of the present invention.

Those skilled in the art will readily observe that numerous modifications and alterations of the device and method may be made while retaining the teachings of the invention. Accordingly, the above disclosure should be construed as limited only by the metes and bounds of the appended claims.

1. A method for fabricating a pad structure, comprising:
providing a material layer;
forming an opening in the material layer;
forming a conductive layer on the material layer and into the opening;
forming a patterned mask on the conductive layer;
performing a first etching process to remove part of the conductive layer for forming a conductive plug; and
performing a shaping process to alter the shape of a top surface of the conductive plug.

2. The method of claim 1, further comprising:
performing the first etching process to remove part of the patterned mask and part of the conductive layer at the same time.

3. The method of claim 2, wherein the step of removing part of the patterned mask comprises shaping the patterned mask from a rectangular shape to a half moon shape.

4. The method of claim 1, wherein the shaping process comprises:
conducting a second etching process to remove part of the material layer and part of the conductive plug so that a top surface of the conductive plug comprises a curved surface.

5. The method of claim 1, wherein a thickness of the conductive plug protruding from a top surface of the material layer is between 500 Angstroms to 700 Angstroms.

6. The method of claim 1, wherein the shaping process comprises:
conducting a second etching process to remove the patterned mask and part of the material layer; and
conducting a third etching process to remove part of the conductive plug so that the conductive plug comprises a slanted sidewall.

7. The method of claim 6, wherein the third etching process comprises using argon to remove part of the conductive plug.

8. The method of claim 1, further comprising:
performing the first etching process to remove the patterned mask and part of the conductive layer at the same time so that the conductive plug comprises a slanted sidewall.

9. The method of claim 8, wherein an etching selectivity of the conductive layer over the patterned mask is 1.0.

10. The method of claim 8, wherein the shaping process comprises:
conducting a second etching process by using the conductive plug comprising the slanted sidewall as mask to remove part of the material layer.

11. A pad structure, comprising:
a material layer; and
a conductive plug in the material layer and protruding from a top surface of the material layer, wherein the conductive plug comprises metal and a top surface of the conductive plug comprises a curved surface.

12. The pad structure of claim 11, wherein the conductive plug comprises a planar sidewall connected to the curved surface.

13. The pad structure of claim 12, wherein the planar sidewall of the conductive plug is aligned with an edge of the material layer.

14. The pad structure of claim 11, wherein the pad structure is a dynamic random access memory (DRAM) storage node pad.

15. A pad structure, comprising:
a material layer; and
a conductive plug in the material layer and protruding from a top surface of the material layer, wherein a top portion of conductive plug comprises a slanted sidewall and a planar sidewall connected to the slanted sidewall and the planar sidewall is aligned with an edge of the material layer.

16. The pad structure of claim 15, wherein a top surface of the conductive plug comprises a planar surface.

17. The pad structure of claim 16, wherein the slanted sidewall is connected to the planar surface.

18-19. (canceled)

20. The pad structure of claim 15, wherein the slanted sidewall is connected to an edge of the material layer.
